(19) United States
(12) Patent Application Publication
(10) Pub. No.: US 2026/0334269 A1
(43) Pub. Date: Oct. 22, 2026

(54) PACKAGING SUBSTRATE AND SEMICONDUCTOR PACKAGE COMPRISING THE SAME

(71) Applicant: Absolics Inc., Covington, GA (US)

(72) Inventor: SI HUN LEE, Covington, GA (US)

(73) Assignee: Absolics Inc., Covington, GA (US)

(21) Appl. No.: 19/651,765

(22) Filed: Apr. 19, 2026

Related U.S. Application Data
(60) Provisional application No. 63/792,322, filed on Apr. 22, 2025.

(51) Int. Cl. H10W 70/692

(52) U.S. Cl. CPC H10W 70/692

(57) ABSTRACT

A packaging substrate according to the present disclosure includes a glass core and a first complex insulating layer disposed on the glass core. The first complex insulating layer includes an elastic insulating layer and a base insulating layer disposed on the elastic insulating layer. A ratio of an elastic modulus of the base insulating layer to an elastic modulus of the elastic insulating layer is 3 or more. In this case, it is possible to provide a packaging substrate capable of efficient signal transmission while suppressing occurrence of a SeWaRe phenomenon in the glass core.

### CROSS-REFERENCE TO RELATED APPLICATION

This application claims the priority benefit under 35 USC § 119 (e) of U.S. Provisional Patent Application No. 63/792,322, filed on Apr. 22, 2025, the entire disclosure of which is incorporated herein by reference for all purposes.

### BACKGROUND

### Technical Field

The present disclosure relates to a packaging substrate and a semiconductor package comprising the same.

### Description of Related Art

In manufacturing an electronic component, implementing a circuit on a semiconductor wafer is referred to as a front-end process (FE: Front-End), and assembling the wafer into a state usable in an actual product is referred to as a back-end process (BE: Back-End), and a packaging process is included in the back-end process.

Recently, four core technologies of the semiconductor industry that have enabled the rapid development of electronic products include semiconductor technology, semiconductor packaging technology, manufacturing process technology, and software technology. Semiconductor technology is developing in various forms such as line widths of micro to nano units, tens of millions of cells, high-speed operation, and large heat dissipation, but a technology for perfectly packaging the same is relatively insufficient. Accordingly, electrical performance of a semiconductor may be determined by packaging technology and electrical interconnection according thereto rather than performance of the semiconductor technology itself.

As a material of a packaging substrate, ceramic or resin is applied. In the case of a ceramic substrate, since a resistance value is high or a dielectric constant is high, it is not easy to mount a high-performance high-frequency semiconductor device. In the case of a resin substrate, although a high-performance high-frequency semiconductor device may be mounted relatively, there is a limitation in reducing a pitch of wiring.

Recently, studies on applying silicon or glass to a high-end packaging substrate are in progress. By forming a through-hole in a silicon or glass substrate and applying a conductive material to the through-hole, a wiring length between a device and a motherboard may be shortened and excellent electrical characteristics may be obtained.

### SUMMARY

A packaging substrate according to an embodiment of the present disclosure includes a glass core and a first complex insulating layer disposed on the glass core.

The first complex insulating layer includes an elastic insulating layer and a base insulating layer disposed on the elastic insulating layer.

A ratio of an elastic modulus of the base insulating layer to an elastic modulus of the elastic insulating layer is 3 or more.

The elastic modulus of the elastic insulating layer may be 3 GPa or less.

A ratio of a tensile strength of the base insulating layer to a tensile strength of the elastic insulating layer may be 5 or more.

A dielectric constant Dk of the base insulating layer at frequency of 5.8 GHz may be 4 or less.

A dielectric loss factor Df of the base insulating layer at frequency of 5.8 GHz may be 0.01 or less.

The elastic insulating layer may include a bis-maleimide resin.

An entire lower surface of the base insulating layer may be disposed in contact with an upper surface of the elastic insulating layer.

A ratio of a thickness of the elastic insulating layer to a thickness of the base insulating layer may be 0.05 to 0.3.

The packaging substrate may include two or more first complex insulating layers.

The packaging substrate may further include a wiring layer between the first complex insulating layers.

An upper surface of the wiring layer may be disposed in contact with a lower surface of the first complex insulating layer disposed on the wiring layer.

A 90° peel strength of the wiring layer with respect to the first complex insulating layer disposed on the wiring layer may be 1 kgf/cm or more.

The packaging substrate may further include a second complex insulating layer disposed under the glass core.

The second complex insulating layer may include the elastic insulating layer and the base insulating layer disposed under the elastic insulating layer.

A ratio of a sum of a total thickness of the first complex insulating layer and the second complex insulating layer to a thickness of the glass core may be 0.7 or more.

### BRIEF DESCRIPTION OF THE DRAWINGS

FIG. 1 is a conceptual diagram illustrating a SeWaRe phenomenon.

FIG. 2 is a cross-sectional view illustrating a packaging substrate according to an embodiment of the present disclosure.

FIG. 3 is a cross-sectional view illustrating a packaging substrate according to another embodiment of the present disclosure.

FIG. 4 is a cross-sectional view illustrating a packaging substrate according to still another embodiment of the present disclosure.

FIG. 5 is an image of the packaging substrate of Example 1.

FIG. 6 is an image of the packaging substrate of Example 2.

FIG. 7 is an image of the packaging substrate of Comparative Example 1.

### DESCRIPTION OF THE EMBODIMENTS

Hereinafter, the present disclosure will be described in detail with reference to the accompanying drawings so that a person having ordinary skill in the art to which the present invention pertains may easily carry out the same. However, the present disclosure may be implemented in various different forms and is not limited to the embodiments described herein. Throughout the specification, like reference numerals are assigned to like parts.

Throughout the present specification, the term “combination thereof” included in a Markush-type expression means a mixture or combination of one or more selected from a group consisting of components described in the Markush-type expression, and means including one or more selected from the group consisting of the components.

Throughout the present specification, terms such as “first,” “second,” or “A,” “B” are used to distinguish the same terms from each other. Further, a singular expression includes a plural expression unless the context clearly indicates otherwise.

In the present specification, “~based” means including a compound corresponding to “~” or a derivative of “~” in a compound.

In the present specification, the meaning that B is positioned on A means that B is positioned directly in contact with A or that B is positioned on A with another layer interposed therebetween, and is not construed as being limited to B being positioned in direct contact with a surface of A.

In the present specification, the meaning that B is connected to A means that A and B are directly connected or are connected through another component therebetween, and is not construed as being limited to A and B being directly connected unless otherwise specified.

In the present specification, unless otherwise specified, a singular expression is interpreted as including a singular or plural interpreted in context.

In the present specification, shapes, relative sizes, angles, and the like of respective components in the drawings are illustrative and may be exaggerated for purposes of description, and rights are not construed as being limited to the drawings.

In the present specification, A and B being adjacent means that A and B are positioned in contact with each other, or that A and B are positioned close to each other without being in contact with each other. The expression that A and B are adjacent is not construed as being limited to A and B being in contact with each other unless otherwise specified.

In the present specification, unless otherwise specified, physical property values of respective components in the packaging substrate are interpreted as being measured at room temperature. Room temperature is 20° C. to 25° C.

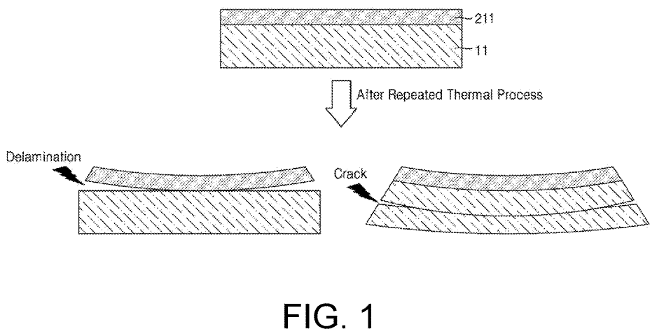

FIG. 1 is a conceptual diagram illustrating a SeWaRe phenomenon. Hereinafter, a problem to be solved of the present disclosure will be described with reference to FIG. 1.

An insulating layer may be formed by disposing a film or composition for forming an insulating layer on a glass core and curing the same in a high-temperature atmosphere. In a process of forming a multilayer insulating layer, due to thermal expansion and contraction of the insulating layer, stress of a considerable magnitude may act on a glass substrate and an electrical connection formed in the insulating layer. Such stress may cause the insulating layer peeling or a SeWaRe phenomenon in which the glass core is split in an in-plane direction during an insulating layer forming process or a substrate dicing process. In addition, the stress may be a major cause of damage to a wiring layer formed in the insulating layer.

It may be considered to introduce an insulating layer having a significantly low modulus on the glass core. However, such an insulating layer has high dielectric properties, and considerable signal loss may occur in a wiring layer surrounded by the insulating layer.

Inventors of the present disclosure experimentally confirmed that, by introducing technical features described below, it is possible to effectively suppress occurrence of a SeWaRe phenomenon in a glass core, to provide excellent electrical reliability, and to provide a packaging substrate capable of efficient signal transmission, and completed the present disclosure.

Hereinafter, the present disclosure will be described in detail.

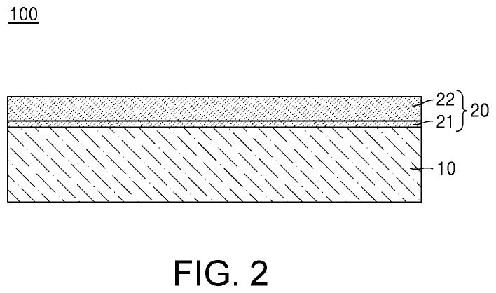

FIG. 2 is a cross-sectional view illustrating a packaging substrate according to an embodiment of the present disclosure. Hereinafter, the present disclosure will be described with reference to FIG. 2.

### Glass Core

The packaging substrate 100 according to the present disclosure may include a glass core 10.

The glass core 10 may have a shape of a glass substrate. The glass core 10 may be, for example, alkali borosilicate plate glass, alkali-free borosilicate plate glass, alkali-free alkali earth borosilicate plate glass, and the like, and any plate glass applied as an electronic component may be applied. The glass core 10 may be a glass substrate for an electronic device, and for example, one manufactured by Schott, AGC, Corning, or the like may be applied, but is not limited thereto.

The glass core 10 may include a through via (not shown) penetrating in a thickness direction of the glass core 10.

The through via includes an internal space (not shown) and an inner via surface (not shown) surrounding the internal space. The internal space means an empty space, and the inner via surface means a surface of the glass core 10 formed inside the through via.

The through via may have a diameter varying in the thickness direction of the glass core 10. The through via may have a substantially uniform diameter in the thickness direction of the glass core 10.

A surface of the glass core 10 may include an upper surface and a side surface connected to the upper surface and formed in the thickness direction of the glass core 10. The surface of the glass core 10 may include a lower surface facing the upper surface.

The side surface being formed in the thickness direction of the glass core 10 is interpreted to include not only that the side surface forms a perpendicular angle with respect to the upper surface of the glass core 10, but also that at least a portion of the side surface forms an angle (inclination angle) other than 90 degrees with the upper surface.

The side surface may be a flat surface or a curved surface.

The glass core 10 may include a cavity (not shown), which is a space formed by recessing an interior.

The cavity may be formed by recessing a portion of an upper surface or a lower surface side of the glass core 10 in the thickness direction of the glass core 10, or may penetrate in the thickness direction of the glass core 10.

A device may be mounted in the cavity such that the packaging substrate 100 and the device are electrically connected. The device is not limited to a semiconductor device such as a CPU, GPU, or memory chip, but may include a capacitor device, a transistor device, an impedance device, or other modules. That is, any semiconductor device mounted in a semiconductor apparatus may be applied as the device without limitation.

A thickness of the glass core 10 may be 100 μm or more. The thickness may be 200 μm or more. The thickness may be 300 μm or more. The thickness may be 3000 μm or less. The thickness may be 2000 μm or less. The thickness may be 1000 μm or less. In this case, it is possible to contribute to providing a packaging substrate 100 having a thinner thickness while stably supporting a redistribution layer formed on the glass core 10.

### Physical Properties and Structure of Complex Insulating Layer

The packaging substrate 100 includes a first complex insulating layer 20 disposed on the glass core 10. The first complex insulating layer 20 includes an elastic insulating layer 21 and a base insulating layer 22 disposed on the elastic insulating layer 21.

The elastic insulating layer 21 is a layer having insulating properties and having higher elasticity than the base insulating layer 22. The elastic insulating layer 21 may function as a buffer layer that relieves stress applied to the glass core 10 in an environment in which temperature increase and decrease are repeated.

The base insulating layer 22 is a layer having insulating properties and supporting a wiring layer to be disposed on the first complex insulating layer 20.

At least a portion of the base insulating layer 22 may be disposed in contact with the elastic insulating layer 21. The base insulating layer 22 may be disposed in contact with the elastic insulating layer 21. An entire lower surface of the base insulating layer 22 may be disposed in contact with an upper surface of the elastic insulating layer 21. That is, in the first complex insulating layer 20, another component may not be disposed between the elastic insulating layer 21 and the base insulating layer 22.

The present disclosure may control a ratio of an elastic modulus of the base insulating layer 22 to an elastic modulus of the elastic insulating layer 21. In this case, in a process of manufacturing the first complex insulating layer 20, it is possible to suppress excessive stress caused by the first complex insulating layer 20 from being applied to the brittle glass core 10. In addition, it is possible to control a mismatch of thermal expansion characteristics between the elastic insulating layer 21 and the base insulating layer 22 to be less than a predetermined level.

The elastic modulus of the elastic insulating layer 21 and the base insulating layer 22 are measured at 23° C. in a pull mode using a Universal Testing Machine (UTM). In measurement, a tensile speed is 1 mm/min, and measurement is performed under an average condition of N=5.

A ratio of an elastic modulus of the base insulating layer 22 to an elastic modulus of the elastic insulating layer 21 may be 3 or more. The ratio may be 5 or more. The ratio may be 7 or more. The ratio may be 10 or more. The ratio may be 13 or more. The ratio may be 17 or more. The ratio may be 20 or more. The ratio may be 45 or less. The ratio may be 40 or less. The ratio may be 35 or less. In this case, it is possible to provide the first complex insulating layer 20 having stable thermal expansion characteristics while suppressing occurrence of a SeWaRe phenomenon in the glass core 10 during a manufacturing process and the like.

An elastic modulus of the elastic insulating layer 21 may be 3 GPa or less. The elastic modulus may be 2 GPa or less. The elastic modulus may be 1 GPa or less. The elastic modulus may be 0.1 GPa or more. The elastic modulus may be 0.2 GPa or more. In this case, it is possible to effectively suppress occurrence of cracks in the glass core 10 in a process in which the base insulating layer 22 is formed through a curing process.

An elastic modulus of the base insulating layer 22 may be 7 GPa or more. The elastic modulus may be 8 GPa or more. The elastic modulus may be 10 GPa or more. The elastic modulus may be 20 GPa or less. In this case, the base insulating layer 22 may stably support and protect the wiring layer.

The present disclosure may control a ratio of a tensile strength of the base insulating layer 22 to a tensile strength of the elastic insulating layer 21. A first complex insulating layer 20 having such characteristics may stably support, fix, and protect a wiring layer to be formed on the first complex insulating layer 20, and may suppress damage to the wiring layer during manufacturing and use.

The tensile strengths of the elastic insulating layer 21 and the base insulating layer 22 are measured using a Universal Testing Machine. The tensile strength is measured under the same conditions as those for measuring the elastic modulus.

A ratio of a tensile strength of the base insulating layer 22 to a tensile strength of the elastic insulating layer 21 may be 5 or more. The ratio may be 5.5 or more. The ratio may be 6 or more. The ratio may be 6.5 or more. The ratio may be 12 or less. In this case, the first complex insulating layer 20 may have excellent durability and may stably maintain electrical reliability of the wiring layer.

A tensile strength of the elastic insulating layer 21 may be 5 MPa or more. The tensile strength may be 7 MPa or more. The tensile strength may be 10 MPa or more. The tensile strength may be 50 MPa or less. The tensile strength may be 40 MPa or less. The tensile strength may be 30 MPa or less. In this case, the elastic insulating layer 21 may help to have elasticity suitable for stress control in the packaging substrate 100.

A tensile strength of the base insulating layer 22 may be 70 MPa or more. The tensile strength may be 80 MPa or more. The tensile strength may be 90 MPa or more. The tensile strength may be 100 MPa or more. The tensile strength may be 200 MPa or less. The tensile strength may be 180 MPa or less. The tensile strength may be 150 MPa or less. In this case, the first complex insulating layer 20 may help to stably support and protect the wiring layer.

When an entire surface of a wiring layer is surrounded by an insulating layer having high dielectric properties, significant signal loss may occur during signal transmission through the wiring layer. The present disclosure may enable smooth signal transmission of the wiring layer by allowing at least a portion of a surface of the wiring layer to be surrounded by the base insulating layer 22 having controlled dielectric properties.

A dielectric constant Dk of the base insulating layer 22 at 5.8 GHz may be 4 or less. The Dk value may be 3.8 or less. The Dk value may be 3.6 or less. The Dk value may be 3.4 or less. The Dk value may be 1 or more.

A dielectric loss factor Df of the base insulating layer 22 at 5.8 GHz may be 0.01 or less. The Df value may be 0.008 or less. The Df value may be 0.006 or less. The Df value may be 0.004 or less. The Df value may be 0.001 or more. The Df value may be 0.002 or more.

In this case, stable signal transmission without excessive signal loss may be achieved through the wiring layer formed on the first complex insulating layer 20.

The Dk value and the Df value of the base insulating layer 22 are measured at room temperature using a dielectric constant measuring instrument.

The present disclosure may adjust a ratio between a thickness of the base insulating layer 22 and a thickness of the elastic insulating layer 21 in the first complex insulating layer 20. In this case, it is possible to suppress excessive thermal expansion of the first complex insulating layer 20 in a thickness direction due to the elastic insulating layer 21, and to suppress damage to electrical connections formed in through vias in the first complex insulating layer 20.

A ratio of a thickness of the elastic insulating layer 21 to a thickness of the base insulating layer 22 may be 0.05 to 0.3. The ratio may be 0.25 or less. The ratio may be 0.22 or less. The ratio may be 0.2 or less. The ratio may be 0.18 or less. The ratio may be 0.07 or more. The ratio may be 0.1 or more. In this case, while stably maintaining thermal expansion characteristics of the first complex insulating layer 20, the elastic insulating layer 21 may effectively relieve stress applied to the glass core 10 as a buffer layer.

A thickness of the elastic insulating layer 21 may be 0.5 μm or more. The thickness may be 1 μm or more. The thickness may be 2 μm or more. The thickness may be 3 μm or more. The thickness may be 10 μm or less. In this case, the elastic insulating layer 21 may have a thickness suitable for functioning as a stress buffer layer.

A thickness of the base insulating layer 22 may be 15 μm or more. The thickness may be 18 μm or more. The thickness may be 20 μm or more. The thickness may be 23 μm or more. The thickness may be 25 μm or more. The thickness may be 28 μm or more. The thickness may be 30 μm or more. The thickness may be 50 μm or less. In this case, the first complex insulating layer 20 may stably support the wiring layer.

At least a portion of a lower surface of the elastic insulating layer 21 may be disposed in contact with an upper surface of the glass core 10. When a wiring layer is formed on the upper surface of the glass core 10, a portion of the lower surface of the elastic insulating layer 21 may be in contact with a portion of the upper surface of the glass core 10 where the wiring layer is not formed.

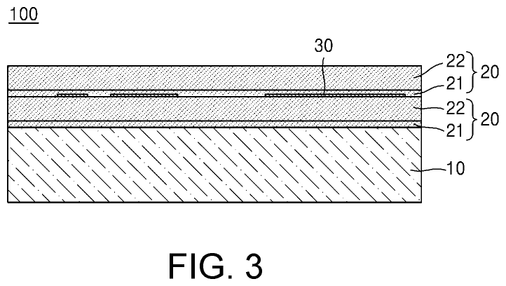

FIG. 3 is a cross-sectional view illustrating a packaging substrate according to another embodiment of the present disclosure. Hereinafter, the present disclosure will be described with reference to FIG. 3.

The packaging substrate 100 includes a glass core 10 and a first complex insulating layer 20 disposed on the glass core 10. Components of the packaging substrate 100 described above with reference to FIG. 2 are applied as they are. Hereinafter, description will be focused on differences.

The packaging substrate 100 may further include a wiring layer 30. The wiring layer 30 is a conductor transmitting an electrical signal. The wiring layer 30 may be electrically connected to a terminal and/or a device in the packaging substrate 100.

The wiring layer 30 may include an electrically conductive material. For example, the wiring layer 30 may include at least one of copper, nickel, aluminum, gold, or silver. Copper or the like may be applied as a material of the wiring layer 30.

The packaging substrate 100 may include a wiring layer 30 disposed on the first complex insulating layer 20. The packaging substrate 100 may further include a wiring layer 30 disposed in contact with an upper surface of the glass core 10. The first complex insulating layer 20 may include a through via. The packaging substrate 100 may further include a wiring layer 30 disposed in the through via.

The packaging substrate 100 may include two or more first complex insulating layers. The packaging substrate 100 may further include a wiring layer 30 disposed between the first complex insulating layers 20. The wiring layer 30 may be disposed in a mixed manner with the first complex insulating layer 20 disposed on the wiring layer 30. The wiring layer 30 may be disposed in a form embedded in the first complex insulating layer 20 disposed on the wiring layer 30. The first complex insulating layer 20 disposed on the wiring layer 30 may surround at least a portion of an upper surface and/or a side surface of the wiring layer 30.

An upper surface of the wiring layer 30 may be disposed in contact with a lower surface of the first complex insulating layer 20 disposed on the wiring layer 30. A lower surface of the wiring layer 30 may be in contact with an upper surface of the first complex insulating layer 20 disposed under the wiring layer 30.

A 90° peel strength of the wiring layer 30 with respect to the first complex insulating layer 20 disposed on the wiring layer 30 may be 1 kgf/cm or more. The peel strength may be 1.2 kgf/cm or more. The peel strength may be 1.4 kgf/cm or more. The peel strength may be 3 kgf/cm or less.

An upper surface of the wiring layer 30 may be in contact with a lower surface of the elastic insulating layer 21 disposed on the wiring layer 30. A 90° peel strength of the wiring layer 30 with respect to the elastic insulating layer 21 disposed on the wiring layer 30 may be 1 kgf/cm or more. The peel strength may be 1.2 kgf/cm or more. The peel strength may be 1.4 kgf/cm or more. The peel strength may be 3 kgf/cm or less.

In this case, the wiring layer 30 may be stably supported and fixed within the packaging substrate 100 to have stable electrical reliability.

The peel strength of the wiring layer 30 is measured as follows.

A multilayer film including the wiring layer 30 and the first complex insulating layer 20 disposed in contact with the wiring layer 30 is peeled from the first complex insulating layer 20 disposed under the wiring layer 30. The multilayer film is turned over, and the peel strength of the wiring layer 30 is measured while peeling the wiring layer 30 from the first complex insulating layer 20 in the multilayer film. The peel strength of the wiring layer 30 is measured using a bond tester according to a 90° peel test. A measurement speed (peel speed) is set to 10 mm/s, and a measurement distance (peel distance) is set to 100 mm. For example, the peel strength value may be measured using a Condor Sigma bond tester manufactured by XYZ TEC.

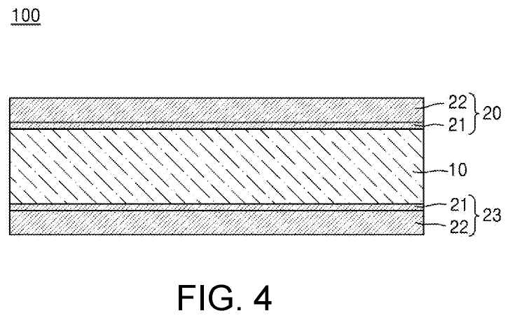

FIG. 4 is a cross-sectional view illustrating a packaging substrate according to still another embodiment of the present disclosure. Hereinafter, the present disclosure will be described with reference to FIG. 4.

The packaging substrate 100 includes a glass core 10 and a first complex insulating layer 20 disposed on the glass core 10. Components of the packaging substrate 100 described above with reference to FIG. 2 are applied as they are. Hereinafter, description will be focused on differences.

The packaging substrate 100 may further include a second complex insulating layer 23 disposed under the glass core 10. The second complex insulating layer 23 may include the elastic insulating layer 21 and the base insulating layer 22 disposed under the elastic insulating layer 21. The elastic insulating layer 21 and the base insulating layer 22 included in the second complex insulating layer 23 correspond to the elastic insulating layer 21 and the base insulating layer 22 described above, respectively. Description of the elastic insulating layer 21 and the base insulating layer 22 included in the second complex insulating layer 23 is omitted as being redundant with the above description.

The packaging substrate 100 may further include a wiring layer (not shown) disposed in contact with a lower surface of the glass core 10. The packaging substrate 100 may further include a wiring layer (not shown) disposed under the second complex insulating layer 23.

The packaging substrate 100 may include two or more layers of each of the first complex insulating layer 20 and the second complex insulating layer 23. The present disclosure may stack the first complex insulating layer 20 and the second complex insulating layer 23, to which the elastic insulating layer 21 is applied, in multiple layers above and below the glass core 10. In this case, even when insulating layers are stacked in multiple layers on the glass core 10, it is possible to suppress the glass core 10 from being split in an in-plane direction.

A ratio of a sum of a total thickness of the first complex insulating layer 20 and the second complex insulating layer 23 to a thickness of the glass core 10 may be 0.7 or more. The ratio may be 0.75 or more. The ratio may be 0.8 or more. The ratio may be 2 or less. The ratio may be 1.8 or less. The packaging substrate 100 of the present disclosure may have stable durability even when such a ratio is applied.

### Composition of Complex Insulating Layer

The elastic insulating layer 21 may include a bis-maleimide resin. The bis-maleimide resin may impart appropriate elastic properties such that the elastic insulating layer 21 may function as a stress buffer layer in the complex insulating layer. In addition, the bis-maleimide resin may allow the elastic insulating layer 21 to have excellent bonding strength with respect to the wiring layer 30, such that even without excessively performing a surface roughening treatment on the wiring layer 30, the wiring layer 30 may be stably fixed to the elastic insulating layer 21. In this case, when driven by applying high-frequency power, the packaging substrate 100 may have much less signal loss compared to a packaging substrate 100 to which an excessively roughened wiring layer 30 is applied.

A number average molecular weight of the bis-maleimide resin may be 4,000 or more. The number average molecular weight may be 7,000 or more. The number average molecular weight may be 10,000 or more. The number average molecular weight may be 15,000 or more. The number average molecular weight may be 50,000 or less. The number average molecular weight may be 45,000 or less. The number average molecular weight may be 40,000 or less. The number average molecular weight may be 35,000 or less.

The number average molecular weight of the bis-maleimide resin is measured by gel permeation chromatography (GPC).

The bis-maleimide resin may have a dimer acid skeleton. The bis-maleimide resin may be a resin formed through a reaction of an acid anhydride and a diamine.

The elastic insulating layer 21 may further include an epoxy resin. The elastic insulating layer 21 may further include a cured epoxy resin. The epoxy resin may be any one selected from the group consisting of a bisphenol-type epoxy resin, a novolac-type epoxy resin, a biphenyl-type epoxy resin, an arylalkylene-type epoxy resin, a tetraphenylol ethane-type epoxy resin, a naphthalene-type epoxy resin, an anthracene-type epoxy resin, a phenoxy-type epoxy resin, a dicyclopentadiene-type epoxy resin, a norbornene-type epoxy resin, and combinations thereof.

The elastic insulating layer 21 may include an epoxy resin in an amount of 0.1 parts by weight or more based on 100 parts by weight of the bis-maleimide resin. The elastic insulating layer 21 may include an epoxy resin in an amount of 1 part by weight or more based on 100 parts by weight of the bis-maleimide resin. The elastic insulating layer 21 may include an epoxy resin in an amount of 5 parts by weight or more based on 100 parts by weight of the bis-maleimide resin. The elastic insulating layer 21 may include an epoxy resin in an amount of 15 parts by weight or less based on 100 parts by weight of the bis-maleimide resin. The elastic insulating layer 21 may include an epoxy resin in an amount of 10 parts by weight or less based on 100 parts by weight of the bis-maleimide resin. In this case, it may help the elastic insulating layer 21 to have flexibility suitable for application to the first complex insulating layer 20 and the like, and bonding strength with respect to the wiring layer 30.

The elastic insulating layer 21 may further include a filler. The filler may include an inorganic filler. The inorganic filler may be any one selected from the group consisting of barium sulfate, silica, talc, clay, magnesium carbonate, calcium carbonate, aluminum oxide, aluminum hydroxide, silicon nitride, aluminum nitride, titanium oxide, and combinations thereof.

The elastic insulating layer 21 may further include other additives in addition to the components described above. The additives are not limited as long as they are commonly applied in the packaging substrate field. The additives may include, for example, a curing agent, a coloring agent, and a defoaming agent.

The base insulating layer 22 may include an epoxy resin and a filler. The base insulating layer 22 may include a cured epoxy resin and a filler.

The epoxy resin described above may be applied as the epoxy resin. Description of the epoxy resin is omitted as being redundant with the above description.

The base insulating layer 22 may include an epoxy resin in an amount of 10 wt % or more. The base insulating layer 22 may include an epoxy resin in an amount of 15 wt % or more. The base insulating layer 22 may include an epoxy resin in an amount of 20 wt % or more. The base insulating layer 22 may include an epoxy resin in an amount of 50 wt % or less. The base insulating layer 22 may include an epoxy resin in an amount of 45 wt % or less. The base insulating layer 22 may include an epoxy resin in an amount of 40 wt % or less.

The base insulating layer 22 may include a filler. The base insulating layer 22 may include the filler described above. Description of the filler is omitted as being redundant with the above description.

The base insulating layer 22 may further include other additives in addition to the components described above. The additives are not limited as long as they are commonly applied in the packaging substrate field. The additives may include, for example, a curing agent, a coloring agent, and a defoaming agent.

### Semiconductor Package

A semiconductor package according to another embodiment of the present disclosure includes a packaging substrate and a device electrically connected to the packaging substrate.

The packaging substrate may be mounted on a main board and electrically connected to the main board.

Description of the packaging substrate and the device is omitted as being redundant with the above description.

### Method of Manufacturing Packaging Substrate

A method of manufacturing a packaging substrate according to another embodiment of the present disclosure is a method of manufacturing a packaging substrate including a complex insulating layer forming step of forming a complex insulating layer on a glass core.

Description of the glass core is omitted as being redundant with the above description.

If necessary, a glass core having a wiring layer formed on an upper surface thereof may be prepared.

The complex insulating layer forming step may include an elastic insulating layer forming process of forming an elastic insulating layer on the glass core and a base insulating layer forming process of forming a base insulating layer on the elastic insulating layer.

The elastic insulating layer forming process may be performed by laminating a film for forming an elastic insulating layer on the glass core and curing the same, or by coating a composition for forming an elastic insulating layer on the glass core and then curing the same.

The film for forming an elastic insulating layer or the composition for forming an elastic insulating layer may include a bis-maleimide resin. A number average molecular weight of the bis-maleimide resin may be 4,000 or more. The number average molecular weight may be 7,000 or more. The number average molecular weight may be 10,000 or more. The number average molecular weight may be 15,000 or more. The number average molecular weight may be 50,000 or less. The number average molecular weight may be 45,000 or less. The number average molecular weight may be 40,000 or less. The number average molecular weight may be 35,000 or less.

The number average molecular weight of the bis-maleimide resin is measured by gel permeation chromatography (GPC).

The bis-maleimide resin may have a dimer acid skeleton. The bis-maleimide resin may be a resin formed through a reaction of an acid anhydride and a diamine.

The film for forming an elastic insulating layer or the composition for forming an elastic insulating layer may further include an epoxy resin. The epoxy resin may be any one selected from the group consisting of a bisphenol-type epoxy resin, a novolac-type epoxy resin, a biphenyl-type epoxy resin, an arylalkylene-type epoxy resin, a tetraphenylol ethane-type epoxy resin, a naphthalene-type epoxy resin, an anthracene-type epoxy resin, a phenoxy-type epoxy resin, a dicyclopentadiene-type epoxy resin, a norbornene-type epoxy resin, and combinations thereof.

The film for forming an elastic insulating layer or the composition for forming an elastic insulating layer may include an epoxy resin in an amount of 0.1 parts by weight or more based on 100 parts by weight of the bis-maleimide resin. The elastic insulating layer may include an epoxy resin in an amount of 1 part by weight or more based on 100 parts by weight of the bis-maleimide resin. The elastic insulating layer may include an epoxy resin in an amount of 5 parts by weight or more based on 100 parts by weight of the bis-maleimide resin. The elastic insulating layer may include an epoxy resin in an amount of 15 parts by weight or less based on 100 parts by weight of the bis-maleimide resin. The elastic insulating layer may include an epoxy resin in an amount of 10 parts by weight or less based on 100 parts by weight of the bis-maleimide resin. In this case, the elastic insulating layer may help to have properties suitable for functioning as a stress buffer layer and fixing a wiring layer.

The film for forming an elastic insulating layer or the composition for forming an elastic insulating layer may further include a filler. The elastic insulating layer may include the filler described above. Description of the filler is omitted as being redundant with the above description.

The film for forming an elastic insulating layer or the composition for forming an elastic insulating layer may further include other additives in addition to the components described above. The additives are not limited as long as they are commonly applied in the packaging substrate field. The additives may include, for example, a curing agent, a coloring agent, and a defoaming agent.

An elastic insulating layer may be formed by laminating a film for forming an elastic insulating layer on the glass core and curing the film.

Specifically, the film for forming an elastic insulating layer may be laminated by vacuum-attaching the film onto an upper surface of the glass core and then hot-press attaching the film.

The vacuum attachment of the film for forming an elastic insulating layer may be performed for 10 seconds or more. The vacuum attachment may be performed for 20 seconds or more. The vacuum attachment may be performed for 90 seconds or less.

When hot-press attaching the film for forming an elastic insulating layer, a hot press temperature may be 70° C. or more. The hot press temperature may be 80° C. or more. The hot press temperature may be 200° C. or less. The hot press temperature may be 180° C. or less.

A pressure applied when hot-press attaching the film for forming an elastic insulating layer may be 1 kgf/cm² or more. The pressure may be 3 kgf/cm² or more. The pressure may be 10 kgf/cm² or less.

The hot-press attachment of the film for forming an elastic insulating layer may be performed for 10 seconds or more. The hot-press attachment may be performed for 20 seconds or more. The hot-press attachment may be performed for 90 seconds or less.

The laminated film for forming an elastic insulating layer may be cured to form an elastic insulating layer.

Curing of the film for forming an elastic insulating layer may be performed through two or more heat treatment processes.

In a first heat treatment process, an ambient temperature may be 90° C. or more. The ambient temperature may be 100° C. or more. The ambient temperature may be 110° C. or more. The ambient temperature may be 150° C. or less.

The first heat treatment process may be performed for 10 minutes or more. The first heat treatment process may be performed for 15 minutes or more. The first heat treatment process may be performed for 20 minutes or more. The first heat treatment process may be performed for 60 minutes or less.

In a second heat treatment process, an ambient temperature may be 110° C. or more. The ambient temperature may be 120° C. or more. The ambient temperature may be 130° C. or more. The ambient temperature may be 200° C. or less.

The second heat treatment process may be performed for 10 minutes or more. The second heat treatment process may be performed for 15 minutes or more. The second heat treatment process may be performed for 20 minutes or more. The second heat treatment process may be performed for 60 minutes or less.

The base insulating layer forming process may be performed by laminating a film for forming a base insulating layer on the elastic insulating layer or on a film for forming an elastic insulating layer, or by coating a composition for forming a base insulating layer and then curing the film or composition.

The film or composition for forming a base insulating layer may include an epoxy resin and a filler.

The epoxy resin described above may be applied as the epoxy resin. Description of the epoxy resin is omitted as being redundant with the above description.

The film for forming a base insulating layer may include an epoxy resin in an amount of 10 wt % or more. The film for forming a base insulating layer may include an epoxy resin in an amount of 15 wt % or more. The film for forming a base insulating layer may include an epoxy resin in an amount of 20 wt % or more. The film for forming a base insulating layer may include an epoxy resin in an amount of 50 wt % or less. The film for forming a base insulating layer may include an epoxy resin in an amount of 45 wt % or less. The film for forming a base insulating layer may include an epoxy resin in an amount of 40 wt % or less.

The film for forming a base insulating layer may include a filler. The film for forming a base insulating layer may include the filler described above. Description of the filler is omitted as being redundant with the above description.

The film for forming a base insulating layer may further include other additives in addition to the components described above. The additives are not limited as long as they are commonly applied in a buildup film field. The additives may include, for example, a curing agent, a coloring agent, and a defoaming agent.

A base insulating layer may be formed by laminating a film for forming a base insulating layer on an elastic insulating layer or on a film for forming an elastic insulating layer and curing the film for forming a base insulating layer.

The film for forming a base insulating layer may be disposed in a region where the base insulating layer is to be formed, and the film may be laminated by vacuum attachment and then hot-press attachment.

When vacuum-attaching the film for forming a base insulating layer, a time during which vacuum pressure is applied may be 10 seconds or more. The time may be 20 seconds or more. The time may be 90 seconds or less.

When hot-press attaching the film for forming a base insulating layer, a hot press temperature may be 70° C. or more. The hot press temperature may be 80° C. or more. The hot press temperature may be 200° C. or less. The hot press temperature may be 180° C. or less.

A pressure applied when hot-press attaching the film for forming a base insulating layer may be 3 kgf/cm² or more. The pressure may be 5 kgf/cm² or more. The pressure may be 20 kgf/cm² or less.

After laminating the film for forming a base insulating layer, the laminated film may be additionally hot-press attached.

A pressure applied during additional hot-press attachment of the film for forming a base insulating layer may be 1 kgf/cm² or more. The pressure may be 3 kgf/cm² or more. The pressure may be 10 kgf/cm² or less.

When additionally hot-press attaching the film for forming a base insulating layer, a hot press temperature may be 70° C. or more. The hot press temperature may be 80° C. or more. The hot press temperature may be 200° C. or less. The hot press temperature may be 180° C. or less.

When additionally hot-press attaching the film for forming a base insulating layer, a time during which pressure is applied may be 10 seconds or more. The time may be 20 seconds or more. The time may be 90 seconds or less.

The laminated film for forming a base insulating layer may be cured to form a base insulating layer.

Curing of the film for forming a base insulating layer may be performed through two or more heat treatment processes.

In a first heat treatment process, an ambient temperature may be 90° C. or more. The ambient temperature may be 100° C. or more. The ambient temperature may be 110° C. or more. The ambient temperature may be 150° C. or less.

The first heat treatment process may be performed for 10 minutes or more. The first heat treatment process may be performed for 15 minutes or more. The first heat treatment process may be performed for 20 minutes or more. The first heat treatment process may be performed for 60 minutes or less.

In a second heat treatment process, an ambient temperature may be 110° C. or more. The ambient temperature may be 120° C. or more. The ambient temperature may be 130° C. or more. The ambient temperature may be 200° C. or less.

The second heat treatment process may be performed for 10 minutes or more. The second heat treatment process may be performed for 15 minutes or more. The second heat treatment process may be performed for 20 minutes or more. The second heat treatment process may be performed for 60 minutes or less.

The first complex insulating layer may be formed by forming an elastic insulating layer and forming a base insulating layer on the elastic insulating layer.

The first complex insulating layer may be formed by laminating and curing a film for forming an elastic insulating layer and then laminating and curing a film for forming a base insulating layer on the elastic insulating layer, or by laminating the film for forming an elastic insulating layer and the film for forming a base insulating layer and then simultaneously curing the two films.

If necessary, after forming a wiring layer on the first complex insulating layer, another first complex insulating layer may be formed on the wiring layer so as to surround the wiring layer, thereby forming a redistribution layer on the glass core.

The wiring layer may be formed by a dry method or a wet method.

The dry method is a method in which a seed layer is formed by performing sputtering on a region where the wiring layer is to be disposed, and the wiring layer is formed by performing plating on the region where the seed layer is formed. When forming the seed layer, metals such as titanium, chromium, or nickel may be sputtered, and the metals and copper may be applied together for sputtering. Through sputtering, an anchor effect in which a surface of the glass core or the first complex insulating layer and metal particles interact may appear, thereby improving adhesion of the wiring layer.

The wet method is a method in which, after treating a primer on a portion where formation of a wiring layer is required, forming the seed layer on the primer and metal plating is performed. The primer may include a compound having a functional group such as an amine. Depending on a degree of adhesion intended, the primer may include a compound having a functional group such as an amine and a silane coupling agent together. When the silane coupling agent is applied, a primer layer may be formed by performing pretreatment with the silane coupling agent on a surface to be treated with the primer and then coating a compound having an amine group on the pretreated region.

After forming the seed layer, the wiring layer may be formed by plating a metal. Copper plating may be applied when forming the wiring layer, but is not limited thereto. Before metal plating, portions where formation of the wiring layer is not required in the seed layer may be deactivated, or portions where formation of the wiring layer is required may be activated, and then plating may be performed. As a method for activation or deactivation treatment, a light irradiation treatment such as irradiating a laser having a specific wavelength, a chemical treatment, or the like may be applied. However, after performing metal plating without applying activation or deactivation treatment, the wiring layer may be patterned by etching according to a previously designed shape.

After forming the wiring layer, a first complex insulating layer surrounding the wiring layer may be formed. The first complex insulating layer formed on the wiring layer may be formed in the same manner as described above.

If necessary, a second complex insulating layer may be formed under the glass core using the method applied to forming the first complex insulating layer. The second complex insulating layer may be manufactured by the same method as that for forming the first complex insulating layer, except that the base insulating layer is formed under the elastic insulating layer. Description of the method for forming the second complex insulating layer is omitted as being redundant with the above description.

The method of manufacturing a packaging substrate of the present disclosure may further include forming connection terminals, bumps, a cover layer, or the like on an upper surface and/or a lower surface of the packaging substrate, or mounting a device on the substrate.

Hereinafter, the present disclosure will be described in more detail through specific examples. The following examples are merely examples for helping understanding of the present disclosure, and the scope of the present disclosure is not limited thereto.

### Manufacturing Example: Manufacture of Packaging Substrate

Example 1: An SLK-214 film manufactured by Shin-Etsu, which is a film for forming an elastic insulating layer, was laminated on a glass substrate having a thickness of 650 μm. Specifically, the film for forming an elastic insulating layer was vacuum-attached for 30 seconds in a reduced-pressure atmosphere, and then hot-press attached to the film for forming an elastic insulating layer for 30 seconds at a temperature of 120° C. and a pressure of 3 kgf/cm².

A GL103 film manufactured by AFT, which is a film for forming a base insulating layer, was laminated on the laminated film for forming an elastic insulating layer. After vacuum-attaching the laminated film for forming a base insulating layer for 30 seconds in a reduced-pressure atmosphere, the film for forming a base insulating layer was hot-press attached at a temperature of 120° C. and a pressure of 7 kgf/cm². Thereafter, hot-press attachment was additionally applied to the film for forming a base insulating layer for 60 seconds at a temperature of 120° C. and a pressure of 5 kgf/cm².

In the same manner, films for forming an elastic insulating layer and films for forming a base insulating layer were alternately laminated in 7 layers each on the glass core, and films for forming an elastic insulating layer and films for forming a base insulating layer were alternately laminated in 7 layers each under the glass core.

Thereafter, the substrate was heat-treated at 130° C. for 30 minutes and heat-treated at 165° C. for 30 minutes to form a first complex insulating layer and a second complex insulating layer, thereby manufacturing a packaging substrate. In the packaging substrate, a thickness of the elastic insulating layer was observed to be 5 μm, and a thickness of the base insulating layer was observed to be 35 μm.

Example 2: A packaging substrate was manufactured under the same conditions as in Example 1, except that an SLK-215 film manufactured by Shin-Etsu was applied as the film for forming an elastic insulating layer. In the packaging substrate, a thickness of the elastic insulating layer was observed to be 5 μm, and a thickness of the base insulating layer was observed to be 35 μm.

Example 3: A copper foil having a thickness of 20 μm and having a surface roughened such that an arithmetic average roughness Ra was 500 nm was prepared. A film for forming an elastic insulating layer and a film for forming a base insulating layer were laminated on an upper surface of the copper foil under the same conditions as in Example 1. Thereafter, the copper foil laminate was heat-treated under the same conditions as in Example 1 to form an elastic insulating layer and a base insulating layer.

Comparative Example 1: A packaging substrate was manufactured under the same conditions as in Example 1, except that the film for forming an elastic insulating layer was not applied. In the packaging substrate, a thickness of the base insulating layer was observed to be 35 μm.

### Evaluation Example: Measurement of Physical Properties of Each Insulating Layer

In the packaging substrates of the Examples and Comparative Example, the elastic insulating layer and the base insulating layer were cut to prepare test specimens. Using a Universal Testing Machine, an elastic modulus and a tensile strength of the elastic insulating layer and the base insulating layer of each of the Examples and Comparative Example were measured. When measuring the elastic modulus and the tensile strength, an ambient temperature was set to 23° C.

Thereafter, a dielectric constant Dk and a dielectric loss factor Df at frequency of 5.8 GHz of the base insulating layer of each of the Examples and Comparative Example were measured at room temperature using a dielectric constant measuring instrument.

In Example 3, a 90° peel strength of the copper foil with respect to the elastic insulating layer was measured while peeling the copper foil from the elastic insulating layer. The 90° peel strength of the copper foil was measured using a Condor Sigma bond tester manufactured by XYZ TEC according to a 90° peel test. A measurement speed was set to 10 mm/s, and a measurement distance is set to 100 mm. When a measured value was 1 kgf/cm or more, it was evaluated as Pass, and when a measured value was less than 1 kgf/cm, it was evaluated as Fail.

Measured values and evaluation results of each insulating layer for each of the Examples and Comparative Example are shown in Table 1 below.

### Evaluation Example: Evaluation of Occurrence of SeWaRe Phenomenon

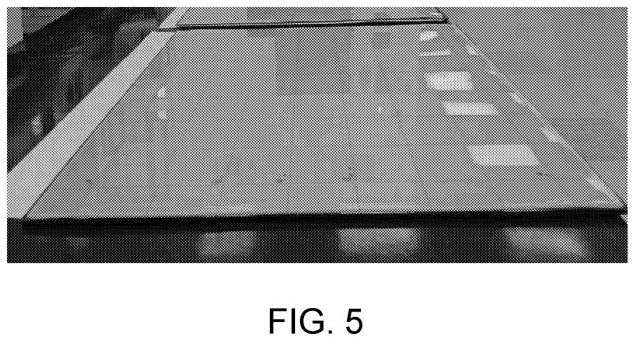

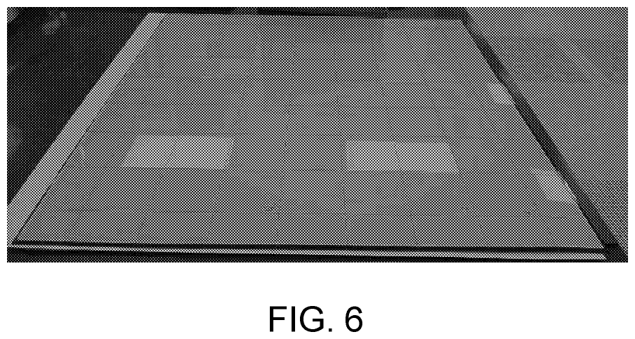

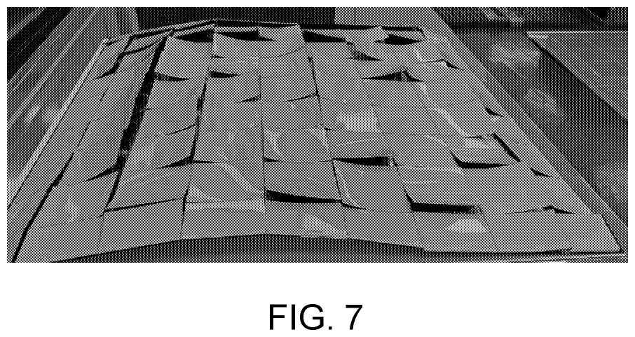

In the packaging substrates of Examples 1 and 2 and Comparative Example 1, whether a SeWaRe phenomenon, in which the glass core is split vertically, occurred was visually confirmed. The packaging substrate of Example 1 is shown in FIG. 5, the packaging substrate of Example 2 is shown in FIG. 6, and the packaging substrate of Comparative Example 1 is shown in FIG. 7.

TABLE 1

| | Ratio of | | | Ratio of | | |
|---|---|---|---|---|---|---|
| | elastic | | | tensile | | |
| | modulus | | | strength | | |
| | of base | | | of base | | |
| | insulating | | | insulating | | |
| | layer to | Elastic | Elastic | layer to | Tensile | Tensile |
| | elastic | modulus | modulus | tensile | strength | strength |
| | modulus | of elastic | of base | strength | of elastic | of base |
| | of elastic | insulating | insulating | of elastic | insulating | insulating |
| | insulating | layer | layer | insulating | layer | layer |
| | layer | (GPa) | (GPa) | layer | (MPa) | (MPa) |
| Example 1 | 26.67 | 0.45 | 12 | 7.24 | 17 | 123 |
| Example 1 | 28.51 | 0.42 | 12 | 8.20 | 15 | 123 |
| Example 1 | 26.67 | 0.45 | 12 | 7.24 | 17 | 123 |
| Comparative | — | — | 12 | — | — | 123 |
| Example 1 | | | | | | |

TABLE 2

| | Dk of base | Df of base | Peel strength evaluation |
|---|---|---|---|
| | insulating layer | insulating layer | of wiring layer |
| Example 1 | 3.3 | 0.0036 | — |
| Example 1 | 3.3 | 0.0036 | — |
| Example 1 | 3.3 | 0.0036 | Pass |
| Comparative | 3.3 | 0.0036 | — |
| Example 1 | | | |

Referring to FIGS. 5 to 7, it may be confirmed that the SeWaRe phenomenon did not occur in Examples 1 and 2, whereas the SeWaRe phenomenon occurred in Comparative Example 1.

Although preferred embodiments of the present invention have been described in detail above, the scope of the present invention is not limited thereto, and various modifications and improvements by a person having ordinary skill in the art using the basic concept of the present invention defined in the following claims also fall within the scope of the present invention.

What is claimed is:

1. A packaging substrate comprising a glass core and a first complex insulating layer disposed on the glass core,
wherein the first complex insulating layer comprises an elastic insulating layer and a base insulating layer disposed on the elastic insulating layer, and
a ratio of an elastic modulus of the base insulating layer to an elastic modulus of the elastic insulating layer is 3 or more.

2. The packaging substrate of claim 1,
wherein an elastic modulus of the elastic insulating layer is 3 GPa or less.

3. The packaging substrate of claim 1,
wherein a ratio of a tensile strength of the base insulating layer to a tensile strength of the elastic insulating layer is 5 or more.

4. The packaging substrate of claim 1,
wherein a dielectric constant Dk of the base insulating layer at frequency of 5.8 GHz is 4 or less.

5. The packaging substrate of claim 1,
wherein a dielectric loss factor Df of the base insulating layer at frequency of 5.8 GHz is 0.01 or less.

6. The packaging substrate of claim 1,
wherein the elastic insulating layer comprises a bis-maleimide resin.

7. The packaging substrate of claim 1,
wherein an entire lower surface of the base insulating layer is disposed in contact with an upper surface of the elastic insulating layer.

8. The packaging substrate of claim 1,
wherein a ratio of a thickness of the elastic insulating layer to a thickness of the base insulating layer is 0.05 to 0.3.

9. The packaging substrate of claim 1,
comprising two or more the first complex insulating layer,
further comprising a wiring layer disposed between the first complex insulating layers,
wherein an upper surface of the wiring layer is disposed in contact with a lower surface of the first complex insulating layer disposed on the wiring layer, and
a 90° peel strength of the wiring layer with respect to the first complex insulating layer disposed on the wiring layer is 1 kgf/cm or more.

10. The packaging substrate of claim 1,
further comprising a second complex insulating layer disposed under the glass core,
wherein the second complex insulating layer comprises the elastic insulating layer and the base insulating layer disposed under the elastic insulating layer, and
a ratio of a sum of a total thickness of the first complex insulating layer and the second complex insulating layer to a thickness of the glass core is 0.7 or more.
